(19) United States
(12) Patent Application Publication
(10) Pub. No.: US 2004/0131205 A1
(43) Pub. Date: Jul. 8, 2004

(54) Device for monitoring musical performances and/or audio signals from video games or similar

(76) Inventor: Jose Ramon Labiaga Larrea, Madrid (ES)

Correspondence Address: John C. McMahon, PO Box 30069, Kansas City, MO, 64112, US

(21) Appl. No.: 10/739,804

(22) Filed: Dec. 18, 2003

(30) Foreign Application Priority Data
Jun. 19, 2001 (ES) U200101589
Jun. 19, 2002 (WO) PCT/ES02/00305

(51) Int. Cl. H04H 5/00; H03G 5/00

(52) U.S. Cl. 381/99; 381/11; 381/1

(57) ABSTRACT

Comprising:

A circuit that is used to mix a stereo input signal with another monaural input signal, independently amplifying and/or attenuating the mixture of both signals.

Three active frequency dividers that are used to separate the low, medium, and high frequencies.

Three independent amplifiers for the three previously separated frequency ranges.

A sub-bass generator connected to the outlet of the low frequency monaural amplifier.

A headphone and/or a two-way baffle system connected to the outlets of the medium and high frequency amplifiers. Optionally, said amplifier outlets can be the two channels of a stereo amplifier.

### OBJECT OF THE INVENTION

The present Utility Model refers to a device for monitoring musical performances and/or audio signals from video games or similar.

### BACKGROUND OF THE INVENTION

Nowadays, musical performance monitoring consists of aiming a sound beam of the performance sound towards the area where the persons producing said sound are located, so that they can hear themselves in order to keep the tempo and/or the tone and avoid loosing the beat.

Such monitoring is usually achieved by means of loudspeakers (monitors), which represent a disadvantage when there are instruments whose frequency range extends below 400 hertz, such as basses, keyboards, and synthesizers, since they require a high sound level in order to be audible during monitoring, which may cause sound coupling, besides the need for using monitors with a higher power, weigh and cost. In addition, the monitoring of these instruments cannot be achieved with headphones because they do not reach such low frequency ranges.

On the other hand, computer and games consoles video games are provided with sound effects that enhance their realism. Still, the realism could be much more enhanced when providing the user with another type of signal different from the visual and/or sound signals, such as vibrations, etc.

### DESCRIPTION OF THE INVENTION

The device of the invention, due to its constitution and use, is highly suitable for monitoring musical performances and/or for using in video games for games consoles, computers, etc., having a cost-effective and simple constitution.

According to the invention, the device comprises:

A circuit that is used to mix a stereo input signal with another monaural input signal, controlling said signal and independently amplifying and/or attenuating the mixture of both signals.

Three adjustable active frequency dividers, which separate the medium, high, and low frequencies, considering as low frequencies those preferably in the range of 30-400 Hertz, the actuation frequencies of each filter being separately adjustable.

Three amplifiers, which independently amplify/control the frequency ranges separated by the active frequency dividers, the two amplifiers controlling the medium and high frequencies preferably made up of two channels of a stereo amplifier, the amplifier intended to control low frequencies being monaural.

A sub-bass generator, or loudspeaker without a membrane, of the type used in a massage apparatus, which is connected to the outlet of the low-frequency monaural amplifier.

A headphone and/or a two-way baffle system, which is connected to the outlets of the medium and high frequency amplifiers.

Providing the device with a stereo input signal coming from a mixing desk of a musical performance or the like, and a monaural signal from a metronome, rhythm box or any other device used to stay at a chosen tempo, said signals are mixed, adjustably separating the signal mixture by frequencies, and said frequency ranges being amplified separately, so that the outlets of the medium and high frequency amplifiers are connected to the headphones or to the conventional two-way baffle system, so that they are audible for the musicians, whereas the sub-bass generator is located preferably under the seat or on the belt of every musician so that, when vibrating with the low frequency signal provided and independently amplified by the low frequency amplifier, it offers to the musician a tactile feeling that replaces and/or complements the sound signal, not requiring such a high sound level in order to perceive low frequency range instruments as in conventional monitoring, the musician being able to independently adjust the intensity of the vibrations coming from the sub-bass generator. In addition, the monitoring integrates the signal coming from a metronome or rhythm box, which improves the possibilities for musicians of maintaining a homogeneous tempo.

On the other hand, connecting the audio signals, such as the ones generated by video games, to the stereo input of the device, provides at the outlet, the high and medium frequencies thereof that can be heard by means of conventional loudspeakers, whereas separated low frequencies trigger the sub-bass generator, which located under the seat or on the belt of a player, will enhance the realism of the game, the monaural input of the device not used remaining in this use mode.

### BRIEF DESCRIPTION OF THE DRAWINGS

FIG. 1 shows schematically the device of the invention.

FIG. 2 is a view showing the device of the invention.

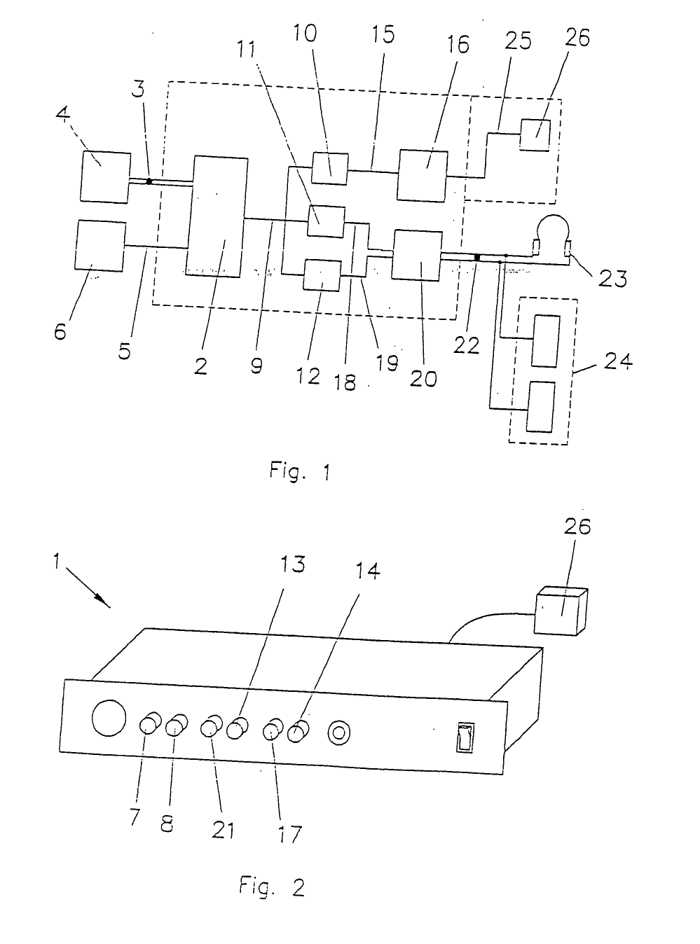

### DESCRIPTION OF A PRACTICAL EMBODIMENT OF THE INVENTION

The device 1 of the invention comprises a circuit 2 that is used to mix a stereo input signal 3 coming from a mixing desk 4 with a monaural signal 5 generated by a rhythm box 6, with corresponding attenuators 7, 8 of said input signals. The circuit 2 mixes, controls, and amplifies/attenuates these input signals by means of attenuators 7 and 8, connecting outlet 9 thereof to three filters 10, 11, and 12 which separate the high, medium, and low frequencies, said filters being independently adjustable by means of corresponding quad potentiometers 13, 14.

Outlet 15 of the low frequency filter 10 is connected to a monaural amplifier 16 which has an independent adjusting knob 17, whereas outlets 18 and 19 of medium and high frequency filters 11 and 12 are connected to the two channels of a stereo amplifier 20, with an adjustable knob 21 whose outlet 22 is connected to headphones 23 or to baffles 24, whereas outlet 25 of the amplifier 16 drives a sub-bass generator 26 which can be located under the seat or on the belt of the musician or player.

While the nature of the invention, as well as the practical embodiment thereof, has been sufficiently described, it should be mentioned that the provisions previously mentioned and represented in the attached drawings are subject to detail changes and in no event shall alter the main aspects of the invention.

1. Device for monitoring musical performances and/or audio signals from video games or similar, characterized in that it comprises a circuit for mixing/attenuating a stereo input signal and a monaural signal, whose outlet is connected to three active frequency dividers which separate the low, medium, and high frequencies, whose outlets are independently connected to three independent amplifiers of the three frequency ranges, the outlet of the low frequency amplifier driving a sub-bass generator while headphones or a conventional two-way baffle system are connected to the outlets of the medium and high frequency amplifiers.

2. Device according to claim 1, characterized in that the medium and high frequency amplifiers are made up of two channels of a stereo amplifier.
